(19) United States
(12) Patent Application Publication
(10) Pub. No.: US 2025/0151421 A1
(43) Pub. Date: May 8, 2025

(54) Semiconductor Device and Method of Making a Semiconductor Package with a Pre-Installed Glass Cover

(71) Applicant: UTAC Headquarters Pte. Ltd., Singapore (SG)

(72) Inventors: Jeffrey Punzalan, Singapore (SG); Catherine Chang, Singapore (SG); Il Kwon Shim, Singapore (SG)

(73) Assignee: UTAC Headquarters Pte. Ltd., Singapore (SG)

(21) Appl. No.: 18/926,920

(22) Filed: Oct. 25, 2024

Related U.S. Application Data
(60) Provisional application No. 63/595,577, filed on Nov. 2, 2023.

(51) Int. Cl. H01L 27/146; H01L 21/56; H01L 21/78; H01L 23/00

(52) U.S. Cl. CPC H10F 39/024; H01L 21/56; H01L 24/83; H01L 24/85; H01L 24/92; H01L 21/78; H01L 2224/83191; H01L 2224/85986; H01L 2224/92147

(57) ABSTRACT

A semiconductor device has a photonic semiconductor die and a lens mounted onto the photonic semiconductor die. The photonic semiconductor die and lens are singulated prior to mounting the lens onto the photonic semiconductor die. An adhesive bead is formed on the photonic semiconductor die to seal a cavity between the lens and photonic semiconductor die. The photonic semiconductor die and lens are disposed into a storage media for transporting the photonic semiconductor die to a semiconductor packaging facility. The photonic semiconductor and lens are disposed on a substrate after mounting the lens onto the photonic semiconductor die. An encapsulant is deposited over the substrate, lens, and photonic semiconductor die.

### CLAIM OF DOMESTIC PRIORITY

The present application claims the benefit of U.S. Provisional Application No. 63/595, 577, filed Nov. 2, 2023, which application is incorporated herein by reference.

### FIELD OF THE INVENTION

The present invention relates in general to semiconductor devices and, more particularly, to a semiconductor device and method of making a semiconductor package with a pre- installed glass cover.

### BACKGROUND OF THE INVENTION

Semiconductor devices are commonly found in modern electronic products. Semiconductor devices perform a wide range of functions, such as signal processing, high-speed calculations, sensors, transmitting and receiving electromagnetic signals, controlling electronic devices, converting optical signals into electrical signals, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Optically sensitive semiconductor devices commonly have a lens or other optically transmissive lid or cover disposed over a photonic or photosensitive circuit on a semiconductor die. Packaging the semiconductor die typically includes depositing an encapsulant or molding compound around the semiconductor die while leaving the lens exposed. Applying the lens onto the semiconductor die during packaging is a problematic step for many reasons.

One of the most serious problems is the threat of foreign material coming into contact with the image sensor surface during handling and packaging of the die. The image sensor is exposed to the environment during handling and processing, which leaves the optical surface susceptible to foreign material coming into contact with the image sensor. Foreign material on an optical semiconductor die is a major source of device failure. However, controlling foreign material during die transfer and manufacturing processes is difficult. Therefore, a need exists for an improved semiconductor device and method of making a semiconductor package with a glass cover.

### BRIEF DESCRIPTION OF THE DRAWINGS

FIGS. 1a-1c illustrate a semiconductor wafer with a plurality of semiconductor die separated by a saw street;

FIGS. 2a-2c illustrate forming lenses for optical semiconductor packages;

FIGS. 3a-3c illustrate lenses formed in another embodiment;

FIGS. 4a-4i illustrate a process of applying a lens to an optical semiconductor die;

FIGS. 5a-5e illustrate transferring the optical semiconductor die with lenses to a waffle tray;

FIGS. 6a-6f illustrate forming a semiconductor package with the optical semiconductor die and pre-applied lenses; and

FIG. 7 illustrates incorporating an optical semiconductor package into a larger electronic device.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are mounted to a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

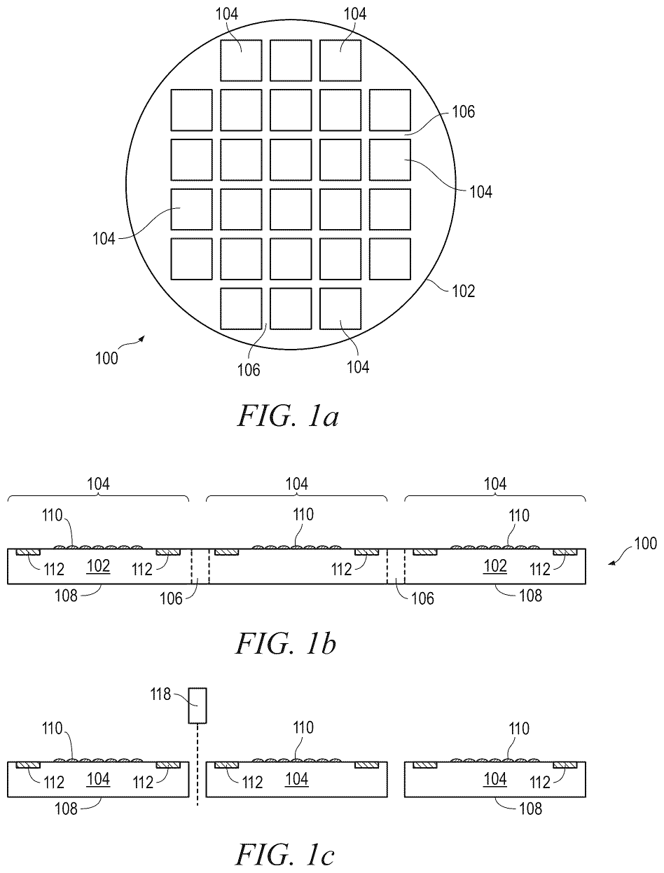

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104.

FIG. 1b shows a cross-sectional view of a portion of semiconductor wafer 100. Each semiconductor die 104 has a back or non-active surface 108 and an active surface including a photonic circuit 110 and additional analog or digital circuits implemented as active devices, passive devices, conductive layers, and dielectric layers formed over or within the die and electrically interconnected according to the electrical design and function of the die. For example, the circuit may include one or more transistors, diodes, sensors, and other circuit elements to implement analog circuits or digital circuits, such as digital signal processor (DSP), application specific integrated circuits (ASIC), memory, or other signal processing circuit. Semiconductor die 104 may also contain integrated passive devices (IPDs), such as inductors, capacitors, and resistors, for RF signal processing. Semiconductor die 104 can implement a digital camera, luminescence sensor, or any other photosensitive device. In one embodiment, photonic circuit 110 is a CMOS image sensor.

An electrically conductive layer 112 is formed over the active surface using physical vapor deposition (PVD), chemical vapor deposition (CVD), electrolytic plating, electroless plating, or other suitable metal deposition process. Conductive layer 112 can be one or more layers of aluminum (Al), copper (Cu), tin (Sn), nickel (Ni), gold (Au), silver (Ag), platinum (Pt), or other suitable electrically conductive material. Conductive layer 112 operates as contact pads electrically connected to the circuits on the active surface. In FIG. 1c, semiconductor wafer 100 is singulated through saw street 106 using a saw blade or laser cutting tool 118 into individual semiconductor die 104. The individual semiconductor die 104 can be inspected and electrically tested for identification of known-good die (KGD) post singulation.

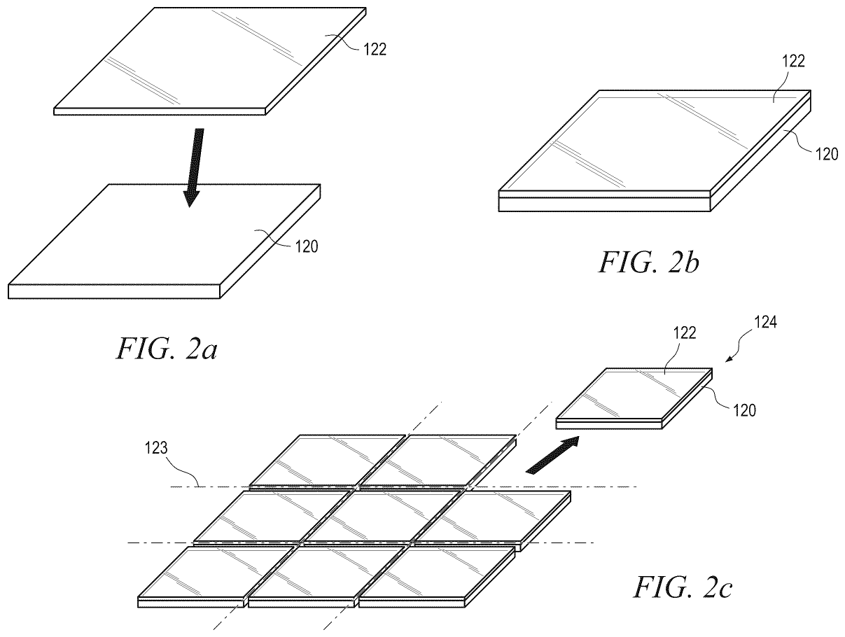

FIGS. 2a-2c illustrate preparation of lenses for use over optical semiconductor die 104 in semiconductor packages. FIG. 2a shows a sheet or plate of lens material 120. Lens material 120 is formed from glass, polymer, or another optically transparent or transmissive material. A protective tape 122 optionally is laminated over lens material 120. Tape 122 can be any suitable material, e.g., polyimide or another polymer. In one embodiment, tape 122 is formed from a material that is able to withstand the heat of standard epoxy molding. Tape 122 optionally has a layer of thermal release adhesive that releases at or above the molding temperature of semiconductor packages being formed to ensure that the tape remains intact during the encapsulation process. FIG. 2b shows the panel of lens material 120 with tape 122 laminated thereon.

In FIG. 2c, lens material 120 is singulated into a plurality of individual lenses 124. Lenses 124 are singulated through saw streets 123 using a saw blade, laser cutting tool, or other suitable device or process. Each lens 124 has a corresponding portion of tape 122 remaining to cover the top surface of the lens.

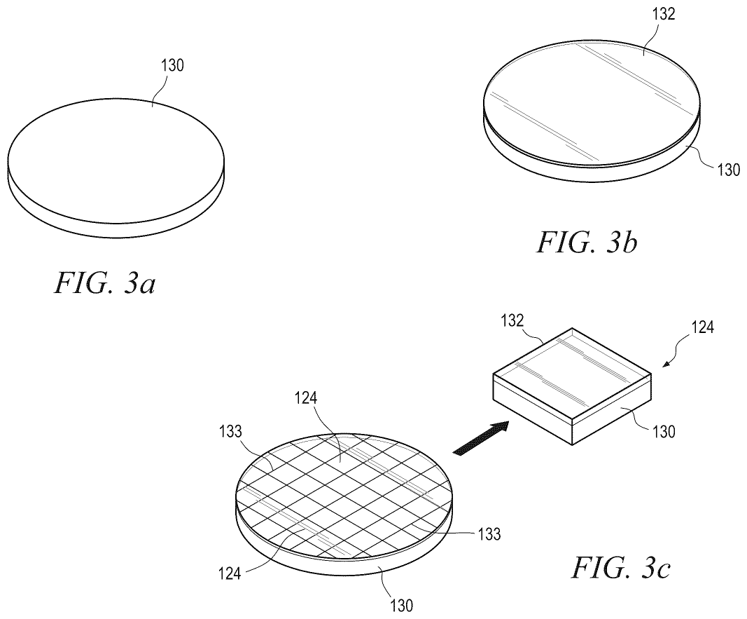

FIGS. 3a-3c illustrate forming lenses by an alternative process. FIG. 3a starts with a wafer 130 of lens material. The lens material can again be any suitable optically transmissive or transparent material, such as glass or polymer. In FIG. 3b, an optional protective layer 132 is formed over wafer 130. Protective layer 132 is formed using paste printing, spin coating, or another suitable process. In some embodiments, protective layer 132 is formed from a washable epoxy that is heat resistant and removable using a chemical agent or water. Protective layer 132 is applied as a liquid and then cured in one embodiment. FIG. 3c shows an individual lens 124 singulated from wafer 130 by cutting through saw streets 133 with a saw blade or laser cutting tool.

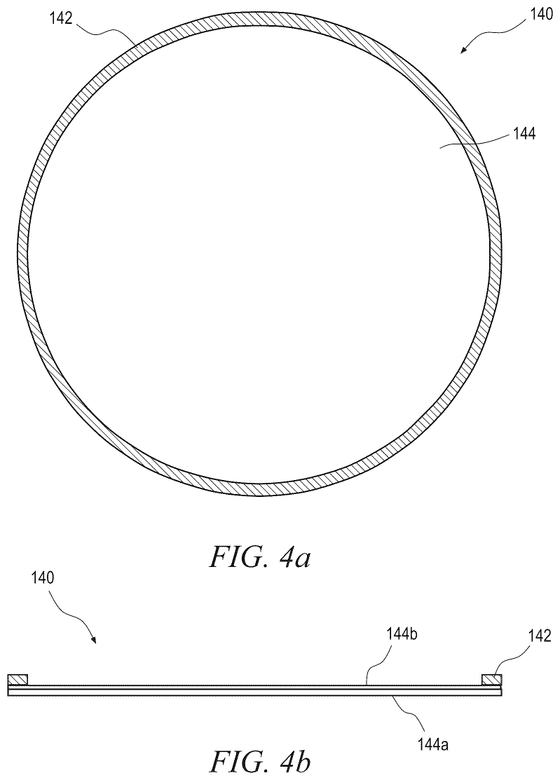

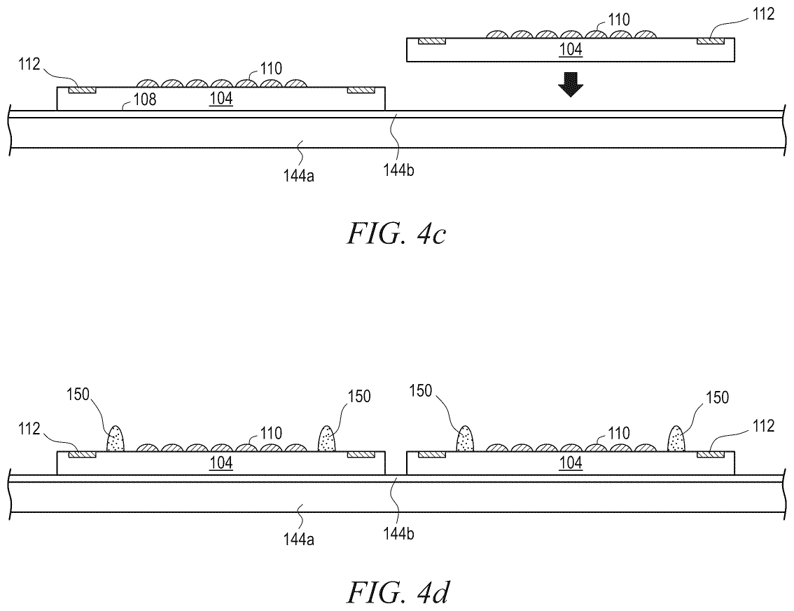

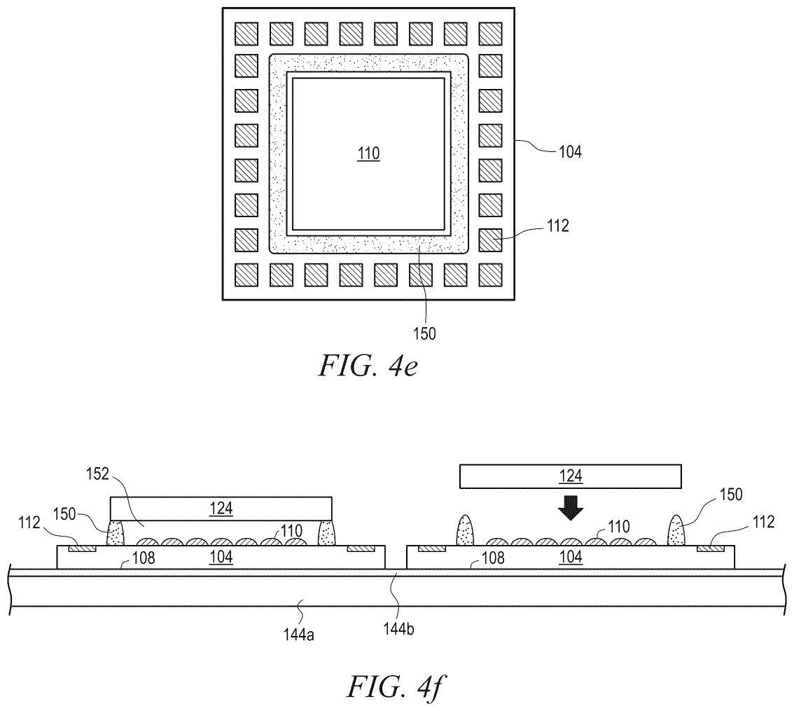

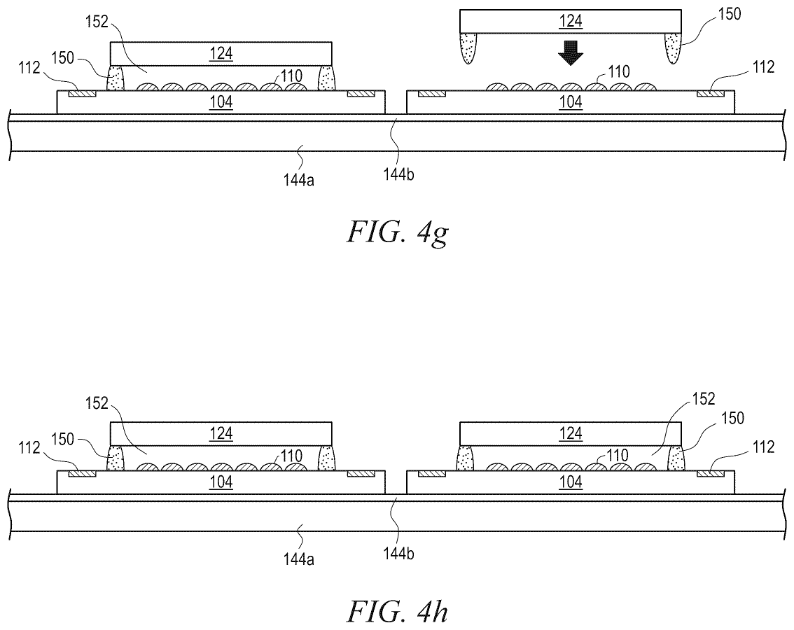

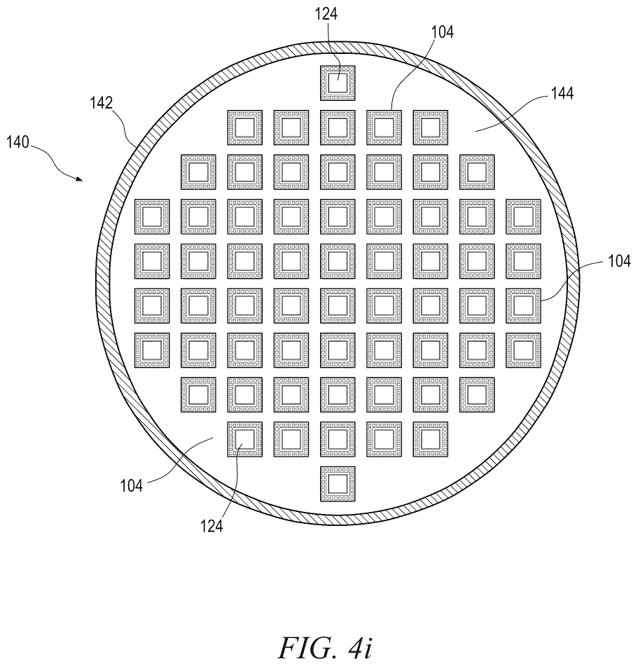

FIGS. 4a-4i illustrate applying lenses 124 to semiconductor die 104. The illustrated process typically occurs in the same clean room where manufacturing of semiconductor die 104 has recently been completed. In some embodiments, lenses 124 are also formed in the same room. In other embodiments, lenses 124 are shipped to the semiconductor die 104 manufacturer as a wafer or panel and then singulated and processed in the same room in which the semiconductor die are manufactured.

FIGS. 4a and 4b illustrate a wafer ring 140. Wafer ring 140 includes a rigid ring 142 and an adhesive tape 144 forming a support structure within the rigid ring. Rigid ring 142 can be formed of a metal, e.g., copper, steel, gold, aluminum, or combinations thereof, polymers, composites, or another suitable rigid material. Adhesive tape 144 includes a polymer or other suitable film or tape 144a, e.g., polyimide, and an adhesive layer 144b disposed on the tape. Adhesive layer 144b attaches tape 144a to rigid ring 142 and keeps the tape taut within the rigid ring. The surface of adhesive 144b remains exposed within rigid ring 142 for subsequent use in holding semiconductor die 104.

In FIG. 4c, semiconductor die 104 are disposed on adhesive tape 144 using pick-and-place or another suitable process. Semiconductor die 104 are disposed directly on adhesive layer 144a and physically held onto wafer ring 140 by the adhesive layer. The area within rigid ring 142 is completely filled in with as many semiconductor die 104 as can be stored within the rigid ring, typically tens, hundreds, or thousands of semiconductor die 104. FIG. 4i below shows an exemplary plan view of wafer ring 140 populated with semiconductor die 104.

In FIG. 4d, an adhesive 150 is dispensed around the photonic circuit 110 of each semiconductor die 104 using an inkjet printing head or another suitable means. In one embodiment, adhesive 150 is an ultraviolet (UV) cured adhesive, thereby allowing adhesive 150 to be cured by a UV light shining through lens 124. In another embodiment, adhesive 150 is a thermally cured adhesive with a curing temperature that is safe for lens 124 and semiconductor die 104 so that the adhesive can be cured without damaging other components.

Adhesive 150 forms a continuous bead completely around the perimeter of photonic circuit 110 as shown in the plan view of FIG. 4e. When a lens 124 is mounted over each photonic circuit 110 in FIG. 4f using a pick-and-place machine or other suitable means, adhesive 150 forms a barrier between the lens and semiconductor die 104 to seal and protect a cavity 152 over the photonic circuit. Adhesive 150 holds a lens 124 in place over each photonic circuit 110. Adhesive 150 is deposited onto lens 124 or semiconductor die 104 prior to disposing the lens onto the semiconductor die. FIG. 4g illustrates the alternative embodiment where adhesive 150 is applied first to lenses 124, and then the lenses are mounted onto semiconductor die 104.

Lens 124 can be singulated from a square or round panel with an optional tape or washable epoxy protective layer. Lens 124 has light-transmissive properties to allow an optical signal to be detected by photonic circuit 110. Lens 124 is formed from glass or a light-transmissive polymer in some embodiments. Lens 124 can have any combination of convex, concave, curved, domed, Fresnel, or other shaped surfaces to guide or focus light as desired. Lens 124 may also be flat as illustrated and operate primarily to physically protect photonic circuit 110 without significantly modifying light transmitted through the lens. Lens 124 can be totally transparent or have a material that filters one or more wavelengths of light.

Each semiconductor die 104 on wafer ring 140 has a lens 124 mounted thereon in FIGS. 4h and 4i. FIG. 4h shows a partial cross-section, and FIG. 4i shows a plan view. Lenses 124 were mounted in the clean room where semiconductor die 104 were manufactured, or in another room shortly thereafter, which eliminates the challenges posed by foreign material getting on photonic circuit 110 while adding the lenses when packaging the semiconductor die during later steps. Adhesive 150 seals cavity 152 over photonic circuit 110 so that the photonic circuit is protected during later manufacturing steps when foreign material would be more likely to land on photonic circuit 110. Yield loss is reduced, thus eliminating unnecessary costs. Pre-installing lens 124 also eliminates the need for downstream cleaning processes that are sometimes used to remove foreign material, further saving costs. Manufacturing throughput (units per hour) is improved by reducing foreign material concerns.

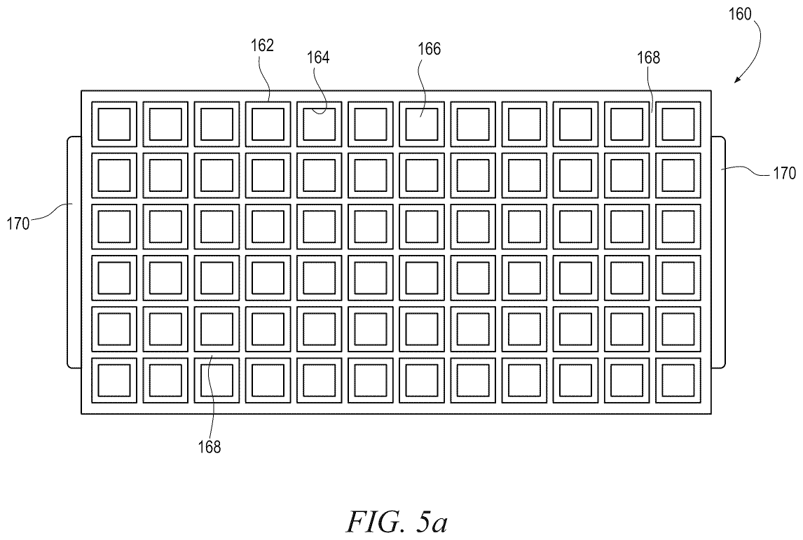

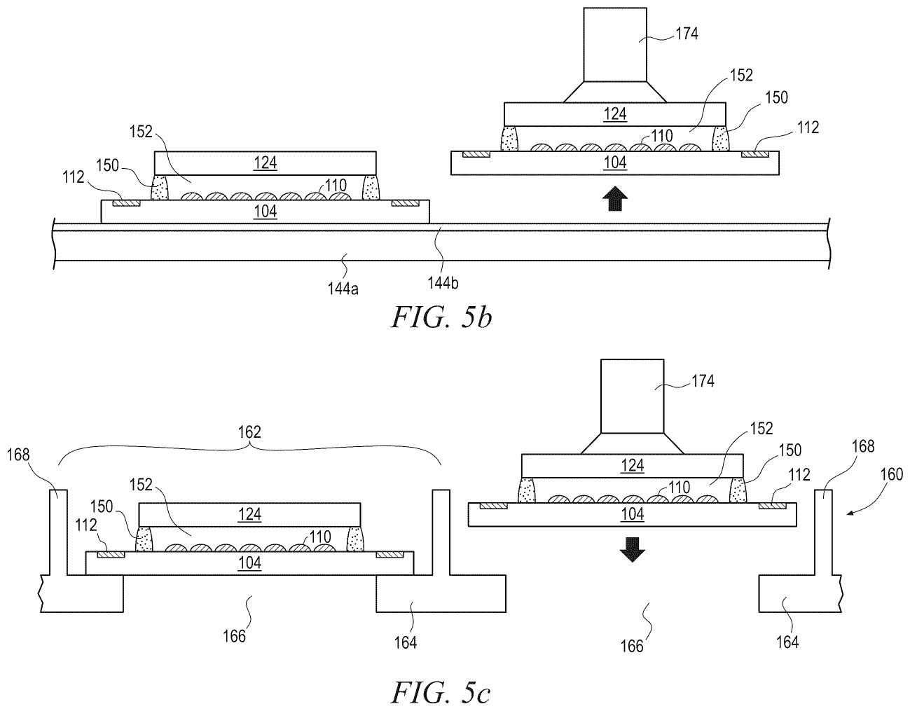

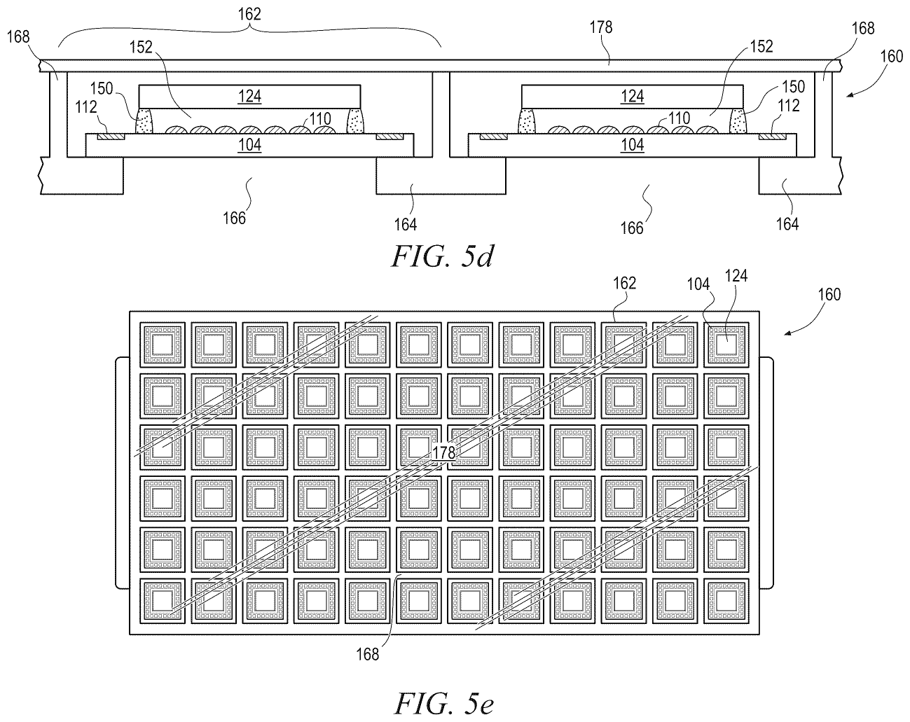

Semiconductor die 104 have lenses 124 mounted thereon by the semiconductor die manufacturing company or facility. Semiconductor die 104 with lenses 124 can be delivered to a packaging company or packaging facility on wafer ring 140 by placing the wafer ring in a storage case or other protective structure for transport. Multiple wafer rings 140 can be stacked or stored in a single case for delivery of more units. In other embodiments, other types of storage media are used, e.g., a JEDEC tray, waffle pack, or tape-and-reel. FIGS. 5a-5e illustrate transferring semiconductor die 104 with lenses 124 to a waffle tray 160 for delivery.

FIG. 5a shows a plan view of waffle tray 160. Waffle tray 160 includes a grid of unit holders 162 distributed across the tray. Each unit holder 162 includes a ledge 164 around the perimeter of the unit holder and an opening 166 formed at the center of the unit holder. Each unit holder 162 is separated from adjacent unit holders by a barrier 168. Tabs or handles 170 are helpful for handling waffle tray 160 and may be configured for gripping by a machine that holds or moves the waffle tray during the packaging process. While one specific embodiment is illustrated, any suitable tray or carrier can be used in other embodiments.

FIG. 5b illustrates a single unit of semiconductor die 104 with lens 124 being picked up off of wafer ring 140 using a pick-and-place head 174. Adhesive layer 144b can be loosened by applying a UV light, thermal energy, or another means suitable for the type of adhesive used. Pick-and-place head 174 uses vacuum suction against lens 124 to lift semiconductor die 104 off of adhesive tape 144. Other lifting mechanisms are used in other embodiments, e.g., a head that pinches semiconductor die 104 between two or more fingers.

Pick-and-place had 174 moves semiconductor die 104 from wafer ring 140 to waffle tray 160, and, in FIG. 5c, places the semiconductor die down into one of the unit holders 162 of waffle tray 160. Semiconductor die 104 sits on ledge 164 over opening 166 in waffle tray 160. In some embodiments, ledge 164 includes a ridge or posts around semiconductor die 104 to keep the semiconductor die in place within unit holder 162. Opening 166 under semiconductor die 104 allows a device to later lift the semiconductor die from waffle tray 160 when removing the semiconductor die for packaging.

Each semiconductor die 104 is transferred from wafer ring 140 to waffle tray 160. In some embodiments, the number of units held by each is different, and die 104 from multiple wafer rings can be stored in a single waffle tray and vice versa. After waffle tray 160 is fully populated with semiconductor die 104, a plastic film 178 is optionally mounted onto waffle tray 160 in FIG. 5d. Plastic film 178 can have an adhesive that sticks or bonds to the top of barriers 168. In other embodiments, heat is used to partially melt plastic film 178 onto the top surfaces of barriers 168. Plastic film 178 covers and encloses each unit holder 162 to secure semiconductor die 104 for transportation.

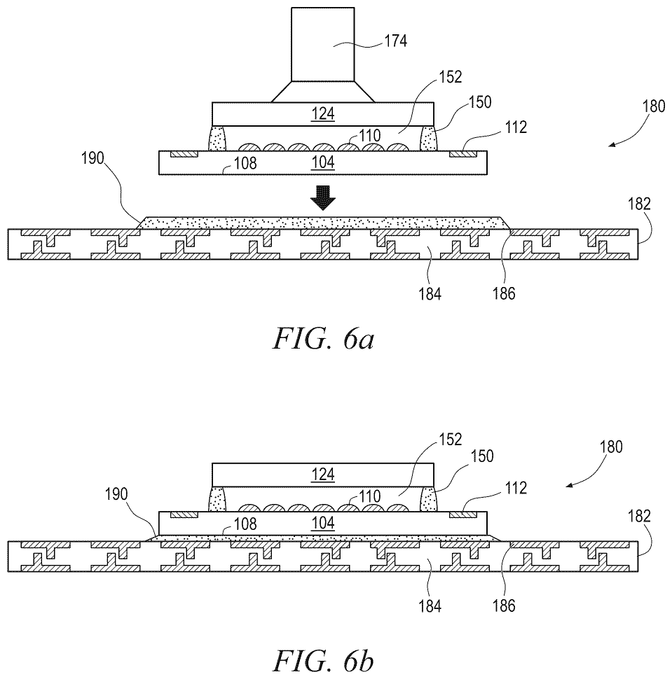

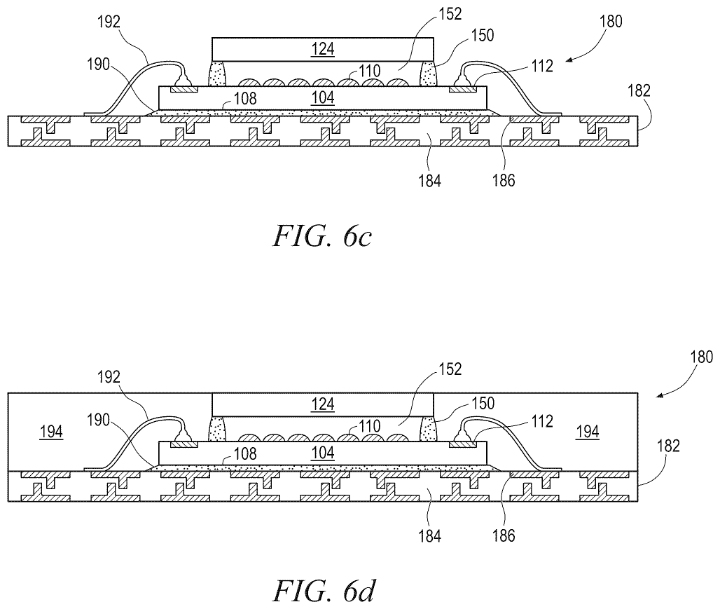

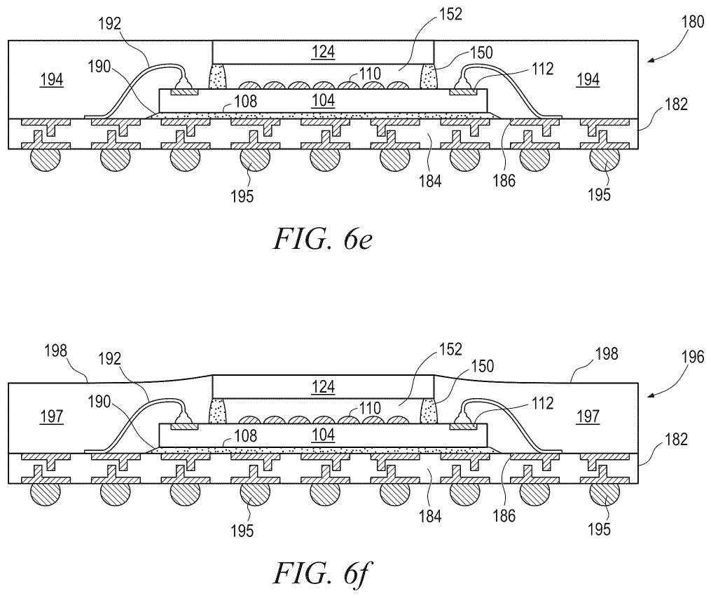

FIGS. 6a-6f illustrate a process of forming a

semiconductor package 180 with semiconductor die 104 having lens 124 pre-installed. A semiconductor packaging company receives a plurality of semiconductor die 104 with lenses 124 preinstalled and is contracted to form semiconductor packages 180 with the semiconductor die. FIG. 6a shows a partial cross-sectional view of a substrate 182. While only a single substrate 182 is shown, hundreds or thousands of substrates are commonly processed on a common carrier, using the same steps described herein for a single unit but performed en masse. Substrate 182 could also start out as a single large substrate with multiple units being formed thereon, which are singulated from each other during or after the manufacturing process.

Substrate 182 includes one or more insulating layers 184 interleaved with one or more conductive layers 186. Insulating layer 184 is a core insulating board in one embodiment, with conductive layers 186 patterned over the top and bottom surfaces, e.g., a copper-clad laminate substrate. Conductive layers 186 also include conductive vias electrically coupled through insulating layers 184. Substrate 182 can include any number of conductive and insulating layers interleaved over each other. A solder mask or passivation layer can be formed over either side of substrate 182. Any suitable type of substrate or leadframe is used for substrate 182 in other embodiments.

A mold underfill or other adhesive 190 is disposed on back surface 108 of semiconductor die 104 or on substrate 182 prior to mounting semiconductor die 104. Adhesive 190 keeps semiconductor die 104 in place during the subsequent manufacturing process. Pick-and-place head 174, or another suitable mechanism, is used to pick up a semiconductor die 104 with lens 124 from wafer ring 140, waffle tray 160, or another suitable storage and delivery mechanism and place the semiconductor die onto substrate 182.

FIG. 6b shows substrate 182 having semiconductor die 104 mounted with photonic circuit 110, contact pads 112, and lens 124 oriented away from the substrate. Adhesive 190 bonds semiconductor die 104 onto substrate 182. Any other discrete active or passive components, other semiconductor die, or other components desired for the intended functionality of semiconductor package 180 can also be mounted onto substrate 182. Any type and number of components can be mounted on both the top and bottom surfaces of substrate 182 or embedded within the substrate.

In FIG. 6c, a plurality of bond wires 192 is formed between contact pads 112 of semiconductor die 104 and contact pads of substrate 182. Bond wires 192 are mechanically and electrically coupled to conductive layer 186 of substrate 182 and to contact pads 112 of semiconductor die 104 by thermocompression bonding, ultrasonic bonding, wedge bonding, stitch bonding, ball bonding, or another suitable bonding technique. Bond wires 192 include a conductive material such as Cu, Al, Au, Ag, a metal alloy, or a combination thereof. Bond wires 192 represent one type of interconnect structure that electrically couples semiconductor die 104 to substrate 182. In other embodiments, solder bumps, conductive pillars, or another suitable interconnect structure is used.

In FIG. 6d, an encapsulant or molding compound 194 is deposited over substrate 182, semiconductor die 104, and lens 124, covering side surfaces of the lens and semiconductor die. Encapsulant 194 is an electrically insulating material deposited using a paste printing, compressive molding, transfer molding, liquid encapsulant molding, vacuum lamination, spin coating, or other suitable application process. Encapsulant 194 can be polymer composite material, such as an epoxy resin, epoxy acrylate, or polymer with or without a filler. Encapsulant 194 is non-conductive and environmentally protects the semiconductor device from external elements and contaminants.

Encapsulant 194 is deposited using film-assisted molding or another method that blocks encapsulant 194 from flowing over the top of lens 124. A top surface of encapsulant 194 is made coplanar to the top surface of lens 124, as illustrated, by the molding process. In other embodiments, encapsulant 194 is deposited over lens 124 and then partially removed by a backgrinding, etching, or other suitable process. Adhesive 150 blocks encapsulant 194 from flowing between lens 124 and semiconductor die 104.

In FIG. 6e, solder bumps 195 are optionally disposed over the bottom surface of substrate 182. A conductive bump material is deposited over substrate 182 opposite semiconductor die 104 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to contact pads of conductive layer 186 using a suitable attachment or bonding process. The bump material can be reflowed by heating the material above its melting point to form conductive balls or bumps 195.

In one embodiment, conductive bumps 195 are formed over an under-bump metallization (UBM) having a wetting layer, barrier layer, and adhesion layer. Conductive bumps 195 can also be compression bonded or thermocompression bonded to conductive layer 186. Conductive bumps 195 represent one type of interconnect structure that can be formed over substrate 182 for electrical connection to a larger electrical system. The interconnect structure can also use bond wires, conductive paste, stud bump, micro bump, conductive pillars, or another type of electrical interconnect. In other embodiments, contact pads of conductive layer 186 remain exposed as a land-grid array.

If a protective layer remains on lens 124, which is typical, the protective layer is removed using a process appropriate for the type of protective layer used, e.g., peeling, washing, chemically dissolving, etching, or otherwise removing using any suitable process. If a plurality of semiconductor packages 180 remains as a larger panel, then the semiconductor packages are singulated from each other using a saw blade, laser cutting tool, or other suitable means.

Semiconductor package 180 in FIG. 6e is complete and ready to be installed into a larger electronic system to provide photonic functionality.

FIG. 6f shows an alternative encapsulant as package 196 with encapsulant 197. Encapsulant 197 is deposited by fill epoxy being deposited over substrate 182 up to the top of lens 124. Surface tension of fill epoxy 197 before curing causes a top surface 198 of the epoxy to extend up the sides of lens 124 while sagging toward the edges of package 196. Encapsulant 197, or any other suitable encapsulation method, can be used in any of the above or below embodiments.

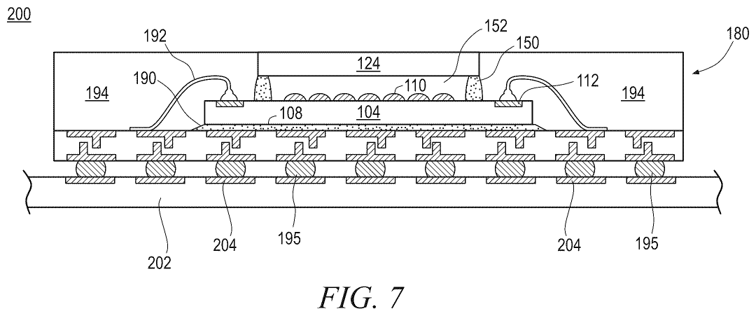

FIG. 7 illustrates integrating the above-described semiconductor packages, e.g., semiconductor package 180, into a larger electronic device 200. FIG. 7 is a partial cross-section of package 180 mounted onto a printed circuit board (PCB) or other substrate 202 as part of electronic device 200.

Bumps 195 are reflowed onto conductive layer 204 of PCB 202 to physically attach and electrically connect semiconductor package 180 to the PCB. In other embodiments, thermocompression or other suitable attachment and connection methods are used. In some embodiments, an adhesive or underfill layer is used between package 180 and PCB 202. Semiconductor die 104 is electrically coupled to conductive layer 204 through substrate 182 to allow use of the functionality of package 180 to the larger system.

Electronic device 200 can have one type of semiconductor package, or multiple types of semiconductor packages, depending on the application. Electronic device 200 can be a stand-alone system that uses the semiconductor packages to perform one or more electrical functions. Alternatively, electronic device 200 can be a subcomponent of a larger system. For example, electronic device 200 can be part of a tablet computer, cellular phone, digital camera, communication system, or other electronic device. Package 180 can operate as, e.g., a camera or luminescence sensor for electronic device 200, converting light rays received through lens 124 into a sensor reading or photographic image for use by a separate general purpose processor on PCB 202.

Semiconductor packages 180 are manufactured with a higher yield due to the use of semiconductor die 104 with pre-applied lenses 124. Lenses 124 are mounted onto semiconductor die 104 prior to delivery to the semiconductor packaging facility. Adhesive 150 creates a sealed cavity 152 such that photonic circuit 110 is protected from foreign material during the handling and packaging process.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a photonic semiconductor die;
mounting a lens onto the photonic semiconductor die;
disposing the photonic semiconductor and lens on a substrate after mounting the lens onto the photonic semiconductor die; and
depositing an encapsulant over the substrate, lens, and photonic semiconductor die.

2. The method of claim 1, further including singulating the photonic semiconductor die and lens prior to mounting the lens onto the photonic semiconductor die.

3. The method of claim 1, further including transporting the photonic semiconductor die to a semiconductor packaging facility after mounting the lens and before disposing the photonic semiconductor die on the substrate.

4. The method of claim 3, further including disposing the photonic semiconductor die and lens into a storage media prior to the transporting step.

5. The method of claim 1, further including forming an adhesive bead on the photonic semiconductor die to seal a cavity between the lens and photonic semiconductor die.

6. The method of claim 1, further including:
forming a bond wire from the photonic semiconductor die to the substrate prior to depositing the encapsulant; and
forming a solder bump on the substrate opposite the photonic semiconductor die.

7. The method of claim 1, further including dispensing and adhesive between the substrate and photonic semiconductor die.

8. A method of making a semiconductor device, comprising:
providing a photonic semiconductor die;
disposing a lens over the photonic semiconductor die; and
disposing the photonic semiconductor and lens over a substrate after disposing the lens over the photonic semiconductor die.

9. The method of claim 8, further including singulating the photonic semiconductor die and lens prior to disposing the lens over the photonic semiconductor die.

10. The method of claim 8, further including transporting the photonic semiconductor die to a semiconductor packaging facility after disposing the lens over the photonic semiconductor die and before disposing the photonic semiconductor die on the substrate.

11. The method of claim 10, further including disposing the photonic semiconductor die and lens into a storage media prior to the transporting step.

12. The method of claim 8, further including forming an adhesive bead on the photonic semiconductor die to seal a cavity between the lens and photonic semiconductor die.

13. The method of claim 8, further including:
forming a bond wire from the photonic semiconductor die to the substrate; and
forming a solder bump on the substrate opposite the photonic semiconductor die.

14. The method of claim 13, further including depositing an encapsulant over the substrate, photonic semiconductor die, lens, and bond wire.

15. A method of making a semiconductor device, comprising:
providing a photonic semiconductor die;
disposing a lens over the photonic semiconductor die; and
dispensing a bead of adhesive between the photonic semiconductor die and lens to seal a cavity between the photonic semiconductor die and lens.

16. The method of claim 15, further including disposing the photonic semiconductor die and lens into a storage media.

17. The method of claim 16, further including:
removing the photonic semiconductor die from the storage media; and
disposing the photonic semiconductor die over a substrate.

18. The method of claim 17, further including:
forming a bond wire from the photonic semiconductor die to the substrate; and
forming a solder bump on the substrate opposite the photonic semiconductor die.

19. The method of claim 18, further including depositing an encapsulant over the substrate, photonic semiconductor die, lens, and bond wire.

20. The method of claim 15, further including singulating the photonic semiconductor die and lens prior to disposing the lens over the photonic semiconductor die.
